(19) United States
(12) Patent Application Publication
(10) Pub. No.: US 2026/0123281 A1
(43) Pub. Date: Apr. 30, 2026

(54) LIGHT-EMITTING DEVICE, DISPLAY SUBSTRATE AND DISPLAY APPARATUS

(71) Applicant: BOE TECHNOLOGY GROUP CO., LTD., Beijing (CN)

(72) Inventors: Lixia QIU, Beijing (CN); Xueqin CHEN, Beijing (CN); Dan WANG, Beijing (CN); Lei CHEN, Beijing (CN); Rongrong GAO, Beijing (CN)

(73) Assignee: BOE TECHNOLOGY GROUP CO., LTD., Beijing (CN)

(21) Appl. No.: 18/696,360

(22) PCT Filed: Jul. 19, 2023
(86) PCT No.: PCT/CN2023/108250

§ 371 Date: Mar. 28, 2024

(30) Foreign Application Priority Data
Jul. 29, 2022 (CN) 202210910661.2

(51) Int. Cl. H10K 85/60; C09K 11/02; C09K 11/06; H10K 50/11; H10K 102/00

(52) U.S. Cl. CPC H10K 85/658; C09K 11/02; C09K 11/06; H10K 85/615; H10K 85/626; H10K 85/633; H10K 85/6574; C09K 2211/1416; C09K 2211/1425; C09K 2211/1441; H10K 50/11; H10K 85/622; H10K 2102/351

(57) ABSTRACT

A light-emitting device (10) includes an anode (101) and a cathode (102), and a light-emitting unit (104) arranged between the anode (101) and the cathode (102). The light-emitting unit (104) includes at least two light-emitting layers (5) and a charge generation layer (6) arranged between two adjacent light-emitting layers (5). At least one light-emitting layer (5) includes a first light-emitting sub-layer (51) and a second light-emitting sub-layer (52), the first light-emitting sub-layer (51) is closer to the anode (101) than the second light-emitting sub-layer (52). The first light-emitting sub-layer (51) includes a first host material and a first guest material; the second light-emitting sub-layer (52) includes a second host material and a second guest material; a triplet energy level of the first host material is greater than that of the second host material, and triplet energy levels of the host materials are greater than those of the guest materials.

### CROSS-REFERENCE TO RELATED APPLICATIONS

This application is a national phase entry under 35 USC 371 of International Patent Application No. PCT/CN2023/108250, filed on Jul. 19, 2023, which claims priority to Chinese Patent Application No. 202210910661.2, filed on Jul. 29, 2022, which are incorporated herein by reference in their entirety.

### TECHNICAL FIELD

The present disclosure relates to the field of display technologies, and in particular, to a light-emitting device, a display substrate and a display apparatus.

### BACKGROUND

In recent years, organic light-emitting diode (OLED) displays, as a new type of flat panel displays, have gradually received more attention. Due to active light emission, high luminous brightness, high resolution, wide viewing angle, fast response speed, saturated colors, lightness and thinness, low energy consumption, flexibility, and other characteristics, the OLED displays are known as dream display and have become a hot mainstream display product in the market.

### SUMMARY

In an aspect, a light-emitting device is provided. The light-emitting device includes an anode and a cathode that are disposed oppositely, and a light-emitting unit disposed between the anode and the cathode. The light-emitting unit includes at least two light-emitting layers and a charge generation layer disposed between two adjacent light-emitting layers in the at least two light-emitting layers.

At least one light-emitting layer in the at least two light-emitting layers includes a first light-emitting sub-layer and a second light-emitting sub-layer, the first light-emitting sub-layer is closer to the anode than the second light-emitting sub-layer. The first light-emitting sub-layer includes a first host material and a first guest material, the second light-emitting sub-layer includes a second host material and a second guest material, and a triplet energy level of the first host material is greater than a triplet energy level of the second host material. Triplet energy levels of host materials are greater than triplet energy levels of guest materials, the host materials include the first host material and the second host material, and the guest materials include the first guest material and the second guest material.

In some embodiments, a difference between the triplet energy level of the first host material and the triplet energy level of the second host material is greater than 0.1 eV.

In some embodiments, a difference between a wavelength peak of light emitted by a light-emitting layer in the at least two light-emitting layers and a wavelength peak of light emitted by each of remaining light-emitting layers in the at least two light-emitting layers is less than or equal to 10 nm.

In some embodiments, each light-emitting layer in the at least two light-emitting layers are configured to emit blue light. A host material and a guest material of each light-emitting layer include fused ring compounds, and the fused ring compound contains three or more benzene rings.

In some embodiments, the fused ring compound includes any of substituted or unsubstituted anthracene, substituted or unsubstituted phenanthrene, substituted or unsubstituted pyrene, and substituted or unsubstituted fluorene.

In some embodiments, a fluorescence quantum yield of the light-emitting layer is greater than or equal to 85%, and the light-emitting layer is a film layer with horizontal orientation.

In some embodiments, the host material includes an anthracene derivative, and the guest material includes any of a pyrene derivative and a boron-containing derivative.

In some embodiments, the boron-containing derivatives is selected from any of structures represented by a following general formula (I).

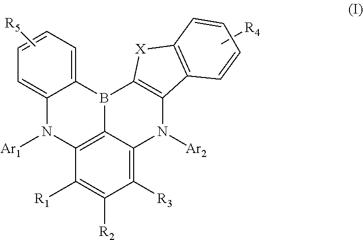

Where X is selected from O, S and NR₆; R₁, R₂, R₃, R₄, R₅, R₆, Ar₁ and Ar₂ are same or different, and are each independently selected from any of H, D, F, substituted or unsubstituted alkyl, substituted or unsubstituted cycloalkyl, substituted or unsubstituted aryl group, substituted or unsubstituted heteroaromatic group, and a substituted or unsubstituted arylamino group.

In some embodiments, the host material includes an anthracene derivative containing deuterium; and the guest material includes a material with a thermal activation delay property.

In some embodiments, the light-emitting unit further includes a red light-emitting layer; the red light-emitting layer includes a phosphorescent material, and the red light-emitting layer contains two types of third host materials. And the light-emitting unit further includes a green light-emitting layer; the green light-emitting layer includes a phosphorescent material, and the green light-emitting layer contains two types of fourth host materials.

The light-emitting device further includes a hole transport unit disposed between the anode and the light-emitting unit. The hole transport unit includes a hole injection layer, a first hole transport layer and a first electron blocking layer that are stacked in a first direction Y. The first direction is a direction from the anode to the cathode.

In some embodiments, the charge generation layer includes a second hole blocking layer, a second electron transport layer, an electron generation layer, a hole generation layer, a second hole transport layer and a second electron blocking layer that are stacked in the first direction. Alternatively, the charge generation layer includes a second hole blocking layer, an electron generation layer, a hole generation layer, a second hole transport layer and a second electron blocking layer that are stacked in the first direction.

In some embodiments, hole mobility of the first hole transport layer is greater than hole mobility of the first electron blocking layer. And/or, hole mobility of the second hole transport layer is greater than hole mobility of the second electron blocking layer.

In some embodiments, triplet energy levels of electron blocking layers are greater than the triplet energy levels of the host materials, and the electron blocking layers include the first electron blocking layer and the second electron blocking layer.

In some embodiments, the light-emitting device further includes an electron transport unit disposed between the cathode and the light-emitting unit. The electron transport unit includes a first hole blocking layer, a first electron transport layer and an electron injection layer that are stacked in the first direction.

In some embodiments, a dimension of the anode in the first direction is in a range of 80 nm to 200 nm, inclusive. A dimension of the hole injection layer in the first direction is in a range of 5 nm to 20 nm, inclusive. A dimension of each of hole transport layers in the first direction is in a range of 10 nm to 100 nm, inclusive. A dimension of each of the electron blocking layers in the first direction is in a range of 20 nm to 70 nm, inclusive. A dimension of each light-emitting layer in the first direction is in a range of 5 nm to 45 nm, inclusive. A dimension of each of hole blocking layers in the first direction is in a range of 2 nm to 20 nm, inclusive. A dimension of each of electron transport layers in the first direction is in a range of 20 nm to 70 nm, inclusive. A dimension of the electron injection layer in the first direction is in a range of 0.5 nm to 10 nm, inclusive. A dimension of the electron generation layer in the first direction is in a range of 5 nm to 20 nm, inclusive. A dimension of the hole generation layer in the first direction is in a range of 5 nm to 20 nm, inclusive. A dimension of the cathode in the first direction is in a range of 10 nm to 30 nm, inclusive.

The hole transport layers include the first hole transport layer and the second hole transport layer; the hole blocking layers include the second hole blocking layer and the first hole blocking layer; and the electron transport layers include the second electron transport layer and the first electron transport layer.

In some embodiments, the light-emitting device further includes a resistance improvement layer disposed on a side of the cathode away from the anode.

In some embodiments, a material of the resistance improvement layer includes a fluorine-containing organic material.

In another aspect, a display substrate is provided. The display substrate includes light-emitting devices each according to any of the above embodiments. The light-emitting device includes an anode and a cathode that are disposed oppositely. The display substrate further includes: a substrate, a pixel defining layer disposed on the substrate, and a plurality of pixel openings defined by the pixel defining layer. Each pixel opening in the plurality of pixel openings is provided with a light-emitting device therein. Cathodes of the light-emitting devices are disposed in a whole layer. The display substrate further includes a plurality of auxiliary electrodes disposed on a side of the cathode away from the anode, and an orthographic projection of each auxiliary electrode in the plurality of auxiliary electrodes on the substrate is located within an orthographic projection of the pixel defining layer on the substrate.

In some embodiments, a dimension of the auxiliary electrode in a first direction is in a range of 10 nm to 20 nm, inclusive. The first direction is a direction from the anode to the cathode.

In yet another aspect, a display apparatus is provided. The display apparatus includes the display substrate as described in any of the above embodiments.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1A is a structural diagram of a light-emitting device, in accordance with some embodiments of the present disclosure;

FIG. 1B is a structural diagram of another light-emitting device, in accordance with some embodiments of the present disclosure;

FIG. 2 is a structural diagram of yet another light-emitting device, in accordance with some embodiments of the present disclosure;

FIG. 3A is a structural diagram of yet another light-emitting device, in accordance with some embodiments of the present disclosure;

FIG. 3B is a structural diagram of yet another light-emitting device, in accordance with some embodiments of the present disclosure;

FIG. 4 is a structural diagram of yet another light-emitting device, in accordance with some embodiments of the present disclosure;

FIG. 5 is a structural diagram of yet another light-emitting device, in accordance with some embodiments of the present disclosure;

FIG. 6 is a structural diagram of a display substrate, in accordance with some embodiments of the present disclosure; and

FIG. 7 is a structural diagram of a display apparatus, in accordance with some embodiments of the present disclosure.

### DETAILED DESCRIPTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The term such as “parallel”, “perpendicular” or “equal” as used herein includes a stated condition and a condition similar to the stated condition. A range of the similar condition is within an acceptable range of deviation. The acceptable range of deviation is determined by a person of ordinary skill in the art in view of measurement in question and errors associated with the measurement of a particular quantity (i.e., limitations of the measurement system). For example, the term “parallel” includes absolute parallelism and approximate parallelism, and an acceptable range of deviation of the approximate parallelism may be a deviation within 5°; the term “perpendicular” includes absolute perpendicularity and approximate perpendicularity, and an acceptable range of deviation of the approximate perpendicularity may also be a deviation within 5°; and the term “equal” includes absolute equality and approximate equality, and an acceptable range of deviation of the approximate equality may be a difference between two equals being less than or equal to 5% of either of the two equals.

It will be understood that when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plan views as idealized exemplary drawings. In the accompanying drawings, thicknesses of layers and sizes of areas are enlarged for clarity. Variations in shapes relative to the accompanying drawings due to, for example, manufacturing technologies and/or tolerances may be envisaged. Therefore, the exemplary embodiments should not be construed to be limited to the shapes of areas shown herein, but to include deviations in the shapes due to, for example, manufacturing. For example, an etched area shown in a rectangular shape generally has a feature of being curved. Therefore, the areas shown in the accompanying drawings are schematic in nature, and their shapes are not intended to show actual shapes of the areas in an apparatus, and are not intended to limit the scope of the exemplary embodiments.

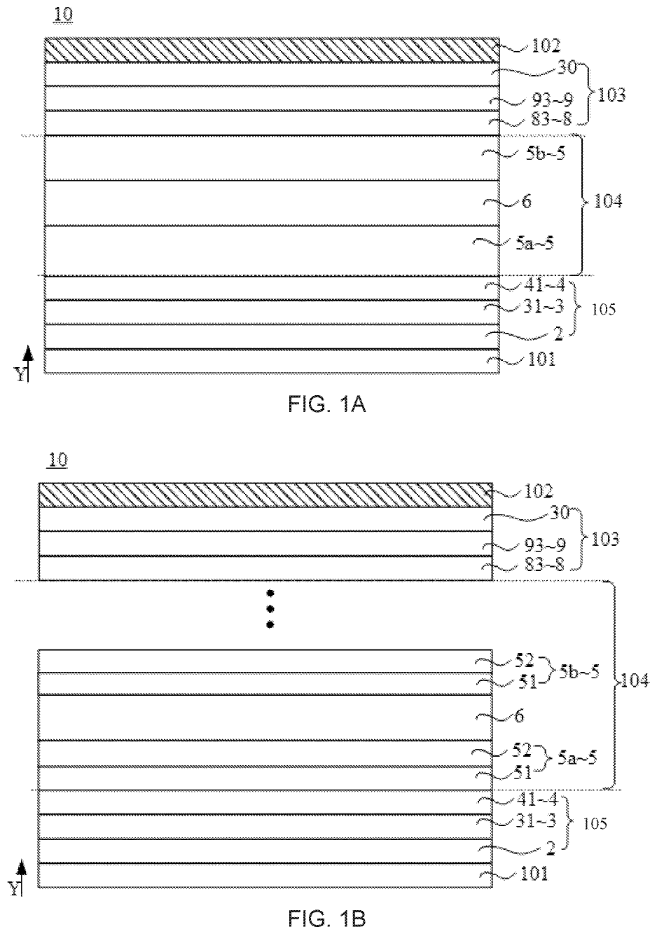

Currently, organic light-emitting diodes (OLEDs) are widely used in the field of flat panel displays due to high brightness, saturated colors, lightness and thinness, flexibility, and other advantages. As shown in FIG. 1A, the light-emitting principle of OLED is as follows. Through a circuit connected to an anode 101 and a cathode 102, the anode 101 is used to inject holes into a light-emitting layer 5, and the cathode 102 is used to inject electrons into the light-emitting layer 5. The formed electrons and holes create excitons in the light-emitting layer 5, and the excitons emit photons by transition back to a ground state through radiation.

However, in the related art, there is a problem that recombination areas of holes and electrons are generated towards an area between an electron blocking layer 4 (e.g., a first electron blocking layer 41) and the light emitting layer 5, resulting in a poor light extraction efficiency of the device. Moreover, another problem in the application of the OLED lies in a low life and efficiency of blue light, resulting in a pink color of the OLED in later stages of display, which restricts the application of the OLED in the display field and makes the OLED unable to be used in devices with long lives.

In conventional technologies, in order to improve blue light performance, efforts are made to develop new light-emitting layer materials. However, after years of development, the potential for improving the lives of light-emitting devices from the material perspective has become smaller and smaller, and the cost has become higher and higher.

The performance of the device mainly depends on properties of materials of all film layers and the device matching structure. In terms of materials, hole mobility of the material, stability of the material, photoluminescence quantum yield (PLQY) of the material, and the like are mainly taken into consideration. In terms of the device matching structure, energy level matching of adjacent film layers, exciton distribution, electron and hole injection and accumulation, and the like are mainly taken into consideration.

Based on this, the present disclosure provides a light-emitting device 10. As shown in FIGS. 1A and 1B, the light-emitting device 10 includes an anode 101 and a cathode 102 arranged oppositely, and a light-emitting unit 104 provided between the anode 101 and the cathode 102. The light-emitting unit 104 includes at least two light-emitting layers 5 and a charge generation layer 6 provided between two adjacent light-emitting layers 5 in the at least two light-emitting layers 5.

For example, as shown in FIG. 1A, the light-emitting unit 104 includes two light-emitting layers 5, namely a first light-emitting layer 5a provided proximate to the anode 101 and a second light-emitting layer 5b provided far away from the anode 101. There is a charge generation layer 6 provided between the first light-emitting layer 5a and the second light-emitting layer 5b.

In some embodiments, as shown in FIG. 1B, at least one light-emitting layer 5 in the at least two light-emitting layers 5 includes a first light-emitting sub-layer 51 and a second light-emitting sub-layer 52, and the first light-emitting sub-layer 51 is closer to the anode 101 than the second light-emitting sub-layer 52. The first light-emitting sub-layer 51 includes a first host material and a first guest material. The second light-emitting sub-layer 52 includes a second host material and a second guest material. A triplet energy level T1 of the first host material is greater than a triplet energy level T2 of the second host material, that is, T1>T2.

For example, a difference between the triplet energy level T1 of the first host material and the triplet energy level T2 of the second host material is greater than 0.1 eV, that is, (T1−T2)>0.1 eV. For example, (T1−T2)=0.2 eV, (T1−T2)=0.3 eV or (T1−T2)=0.4 eV. There is no limit here.

Moreover, triplet energy levels of the host materials are greater than triplet energy levels of the guest materials, where the host materials include the first host material and the second host material, and the guest materials include the first guest material and the second guest material. That is, the triplet energy level T1 of the first host material is greater than a triplet energy level T3 of the first guest material, and the triplet energy level T1 of the first host material is greater than a triplet energy level T4 of the second guest material; moreover, the triplet energy level T2 of the second host material is greater than the triplet energy level T3 of the first guest material, and the triplet energy level T2 of the second host material is greater than the triplet energy level T4 of the second guest material.

It will be noted that the first guest material and the second guest material may be the same or different.

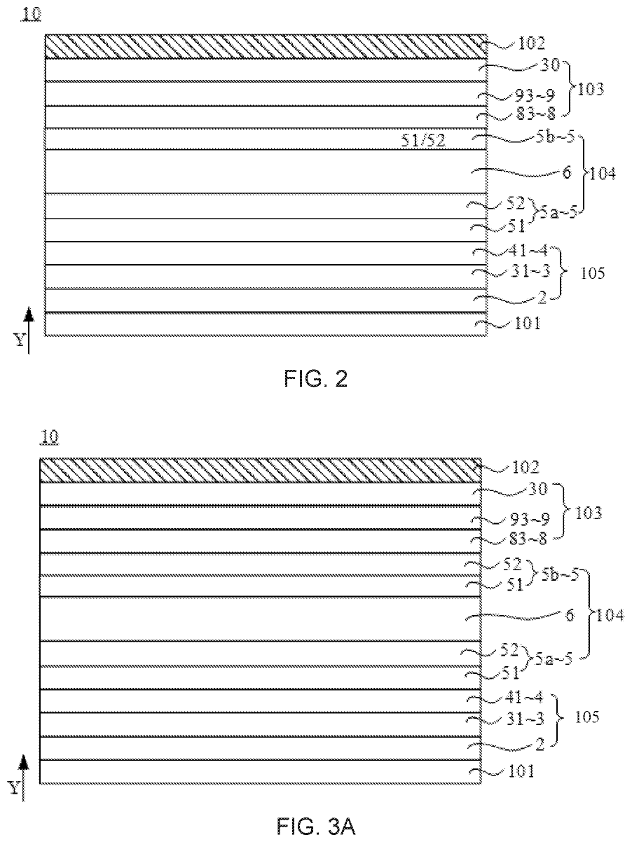

In some examples, as shown in FIG. 2, the light-emitting device 10 includes the anode 101, the light-emitting unit 104 and the cathode 102 that are arranged in a first direction Y. The light-emitting unit 104 includes two light-emitting layers 5, and a charge generation layer 6 provided between the two light-emitting layers 5.

That is, the light-emitting device 10 is a stacked light-emitting device 10.

For example, as shown in FIG. 2, the light-emitting layer 5 proximate to the anode is the first light-emitting layer 5a. The first light-emitting layer 5a includes a first light-emitting sub-layer 51 and a second light-emitting sub-layer 52. The first light-emitting sub-layer 51 is closer to the anode 101 than the second light-emitting sub-layer 52. The triplet energy level T1 of the first host material of the first light-emitting sub-layer 51 is greater than the triplet energy level T2 of the second host material thereof, that is, T1>T2.

By setting the triplet energy level T1 of the first host material to be greater than the triplet energy level T2 of the second host material, and setting the triplet energy levels of the host materials to be greater than the triplet energy levels of the guest materials, electrons and holes may generate excitons in an area where the second light-emitting sub-layer 52 is located, that is, the recombination area of the electrons and the holes is located in the area of the second light-emitting sub-layer 52 of the first light-emitting layer 5a, which is beneficial to balance of excitons, thereby improving the efficiency and life of the light-emitting device 10.

For example, as shown in FIG. 2, the light-emitting layer 5 proximate to the cathode 102 is the second light-emitting layer 5b. The second light-emitting layer 5b may include one layer, and the material of this layer may be the same as the material of the first light-emitting sub-layer 51, or the same as the material of the second light-emitting sub-layer 52.

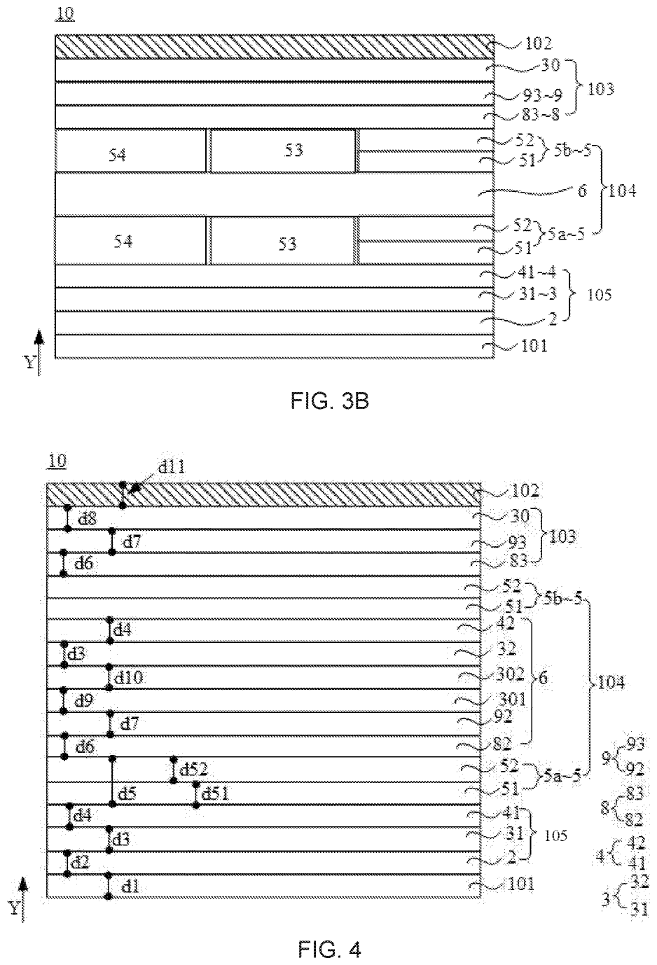

In some examples, as shown in FIG. 3A, the light-emitting device 10 includes the anode 101, the light-emitting unit 104 and the cathode 102 that are arranged in the first direction Y. The light-emitting unit 104 includes two light-emitting layers 5, and a charge generation layer 6 provided between the two light-emitting layers 5.

The two light-emitting layers 5 are a first light-emitting layer 5a and a second light-emitting layer 5b. The first light-emitting layer 5a includes a first light-emitting sub-layer 51 and a second light-emitting sub-layer 52. The first light-emitting sub-layer 51 of the first light-emitting layer 5a is closer to the anode 101 than the second light-emitting sub-layer 52 of the first light-emitting layer 5a. Moreover, the second light-emitting layer 5b includes a first light-emitting sub-layer 51 and a second light-emitting sub-layer 52. The first light-emitting sub-layer 51 of the second light-emitting layer 5b is closer to the anode 101 than the second light-emitting sub-layer 52 of the second light-emitting layer 5b.

Moreover, the first light-emitting sub-layers 51 each include a first host material and a first guest material, and the second light-emitting sub-layers 52 each include a second host material and a second guest material. In the first light-emitting layer 5a, the triplet energy level T1 of the first host material is greater than the triplet energy level T2 of the second host material. In addition, the triplet energy levels of the host materials are greater than the triplet energy levels of the guest materials. As a result, electrons and holes of the first light-emitting layer 5a may generate excitons in an area where the second light-emitting sub-layer 52 of the first light-emitting layer 5a is located, which is beneficial to the balance of the excitons and has a TTF mechanism, thereby improving the efficiency and life of the light-emitting device 10.

In the second light-emitting layer 5b, the triplet energy level T1 of the first host material is greater than the triplet energy level T2 of the second host material. In addition, the triplet energy levels of the host materials are greater than the triplet energy levels of the guest materials. As a result, electrons and holes of the second light-emitting layer 5b may generate excitons in an area where the second light-emitting sub-layer 52 of the second light-emitting layer 5b is located, which is beneficial to the balance of the excitons and has a TTF mechanism, thereby improving the efficiency and life of the light-emitting device 10.

The triplet-triplet fusion (TTF) mechanism refers to a phenomenon in which a singlet exciton is produced by collision between two triplet excitons, which improves fluorescence luminous efficiency. It will be noted that the fluorescence luminous mechanism is that the singlet state emits light and the triplet state does not emit light.

It will be noted that the light-emitting device 10 may include a plurality of light-emitting layers 5, such as three, four or five light-emitting layers 5, which is not limited here. The plurality of light-emitting layers 5 that are stacked may further improve the life and efficiency of the light-emitting device 10.

In some embodiments, as shown in FIGS. 1A to 3B, a difference between a wavelength peak of light emitted by a light-emitting layer 5 in the at least two light-emitting layers 5 and a wavelength peak of light emitted by each of remaining light-emitting layers 5 in the at least two light-emitting layers 5 is less than or equal to 10 nm.

For example, as shown in FIG. 2, both the first light-emitting layer 5a and the second light-emitting layer 5b of the light-emitting device 10 emit blue light. The difference between the wavelength peak of the blue light emitted by the first light-emitting layer 5a and the wavelength peak of the blue light emitted by the second light-emitting layer 5b is 10 nm, 8 nm, 5 nm, 3 nm or 0 nm, and there is no limit here.

By setting a difference between a wavelength peak of light emitted by a light-emitting layer 5 and a wavelength peak of light emitted by each of remaining light-emitting layers 5 to be less than or equal to 10 nm, a difference in the emitted light due to the microcavity effect may be avoided, and color shift of the light-emitting device 10 may be reduced, and a narrow spectrum range of the final emitted light is may be ensured, thereby improving the effect of the light-emitting device 10 emitting light.

In some embodiments, as shown in FIGS. 1A to 3A, each light-emitting layer 5 in the at least two light-emitting layers 5 emits blue light, and the host material and the guest material of the light-emitting layer 5 each include a fused ring compound, and the fused ring compound contains three or more benzene rings.

Since the fused ring compound containing three or more benzene rings (e.g., an anthracene-containing compound) emits blue light itself, the fused ring compound has the TTF mechanism.

In some examples, as shown in FIG. 2, the two light-emitting layers 5 of the light-emitting device 10 are both configured to emit blue light, that is, the first light-emitting layer 5a emits light with a wavelength peak less than or equal to 480 nm, and the second light-emitting layer 5b emits light with a wavelength peak less than or equal to 480 nm. The material of the light-emitting layer 5 includes the fused ring compound containing three or more benzene rings. For example, the fused ring compound includes any of substituted or unsubstituted anthracene, substituted or unsubstituted phenanthrene, substituted or unsubstituted pyrene, and substituted or unsubstituted fluorene.

The structures of anthracene, phenanthrene, pyrene and fluorene are as follows.

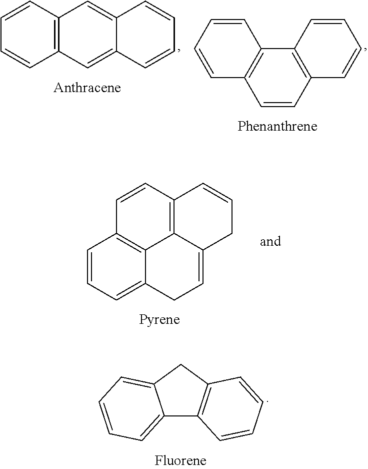

In some embodiments, the host material includes an anthracene derivative, and the guest material includes any of a pyrene derivative and a boron-containing derivative.

For example, as shown in FIG. 2, the light-emitting device 10 includes two light-emitting layers 5. The two light-emitting layers 5 are a first light-emitting layer 5a and a second light-emitting layer 5b. The first light-emitting layer 5a includes a first light-emitting sub-layer 51 and a second light-emitting sub-layer 52. The first host material includes an anthracene derivative, and the second host material includes an anthracene derivative, that is, a substituted anthracene. The first guest material includes any of pyrene derivatives and boron-containing derivatives, and the second guest material includes any of pyrene derivatives and boron-containing derivatives.

In some examples, the boron-containing derivative is selected from any of structures represented by the following general formula (I).

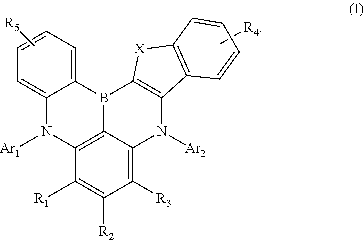

Where X is selected from O, S and NR₆. R₁, R₂, R₃, R₄, R₅, R₆, Ar₁ and Ar₂ are the same or different, and are each independently selected from any of H, D, F, substituted or unsubstituted alkyl, substituted or unsubstituted cycloalkyl, substituted or unsubstituted aryl group, substituted or unsubstituted heteroaromatic group, and a substituted or unsubstituted arylamino group.

For example, the boron-containing derivative is selected from any of the following structures.

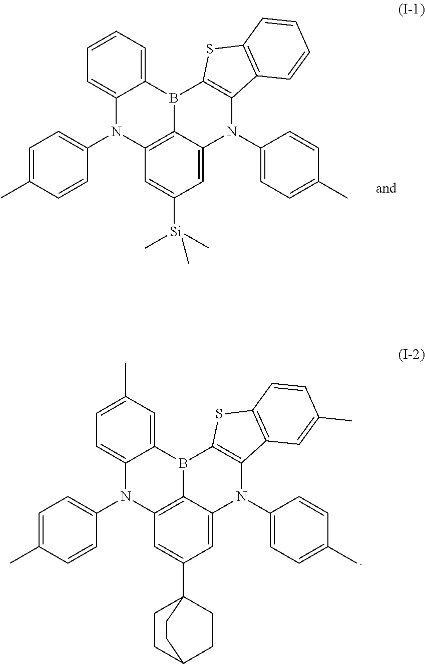

It will be noted that (1-x) in the above structural formulas is a name of each structure but not part of the structural formulas, where x is a positive integer.

In some embodiments, the host material includes an anthracene derivative containing deuterium (D) and the guest material includes a material with a thermally activated delay property.

For example, the anthracene derivative containing deuterium (D) has following structural formulas.

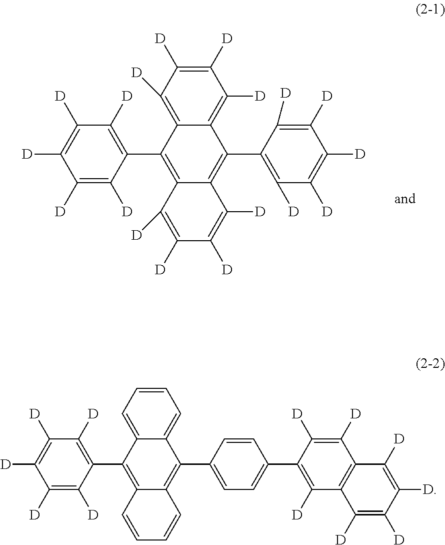

It will be noted that (2-x) in the above structural formulas is a name of each structure but not part of the structural formulas, where x is a positive integer.

Since deuterium is heavy hydrogen, setting deuterium substitution on carbon atoms may increase stability of chemical bonds, so as to improve the thermal stability of the host material and prolong the life of the light-emitting device 10. With the material with thermally activated delay property as the guest material, such guest material can utilize triplet excitons, and may improve the luminous efficiency of the light-emitting device 10.

It will be noted that the material with thermally activated delay property refers to a material with a small energy level difference (AEST) between singlet excitons and triplet excitons.

In some embodiments, as shown in FIGS. 1A to 3B, the fluorescence quantum yield of the light-emitting layer 5 is greater than or equal to 85%, and the light-emitting layer 5 is a film layer having a horizontal orientation.

For example, the fluorescence quantum yield of the light-emitting layer 5 is 85%, 86%, 87%, 88% or 90%, and there is no limit here.

For example, a horizontal direction is arranged perpendicular to the first direction Y, and a vertical direction is arranged parallel to the first direction Y. Setting the light-emitting layer 5 as the film layer with the horizontal orientation is beneficial for the light-emitting layer 5 to emitting light in the vertical direction, thereby improving the light extraction efficiency of the light-emitting device 10.

In some embodiments, as shown in FIG. 3B, the light-emitting unit 104 further includes red light-emitting layers 54, the red light-emitting layer 54 includes a phosphorescent material, and the red light-emitting layer 54 contains two types of third host materials. Moreover, the light-emitting unit 104 further includes green light-emitting layers 53, the green light-emitting layer 53 includes a phosphorescent material, and the green light-emitting layer 5 contains two types of fourth host materials.

It will be noted that the singlet excitons and triplet excitons generated after the phosphorescent material is excited may emit light when transition to the ground state, so that the internal quantum efficiency (IQE) of the light-emitting device 10 based on phosphorescence may reach 100%.

For example, as shown in FIG. 3B, the red light-emitting layer 54 contains two types of third host materials. The two types of third host materials are electron-type materials and hole-type materials. The two types of third host materials may form exciplexes.

For example, as shown in FIG. 3B, the green light-emitting layer 53 contains two types of fourth host materials. The two types of fourth host materials are electron-type materials and hole-type materials. The two types of fourth host materials may form exciplexes.

It will be noted that the electron-type material may be regarded as an electron acceptor material, and the hole-type material may be regarded as an electron donor material. The two materials form an exciplex. In this case, an excited state of the electron acceptor material and a ground state of the electron donor material interact to form a charge transfer state to emit light that has a new spectrum different from an emission spectrum of the hole-type material and an emission spectrum of the electron-type material.

Therefore, the two materials are beneficial to balance of charges, so that an exciton recombination area may move towards the center of the light-emitting layer 5. The final effect is to make hole-electron pairs recombine and emit light in the light-emitting layer 5 effectively, and the exciton recombination area moves towards the center of the light-emitting layer 5, thereby improving the efficiency and life of the light-emitting device 10.

In some embodiments, as shown in FIGS. 1A to 3B, the light-emitting device 10 further includes a hole transport unit 105 provided between the anode 101 and the light-emitting unit 104. The hole transport unit 105 includes a hole injection layer 2, a first hole transport layer 31 and a first electron blocking layer 41 that are stacked in the first direction Y. The first direction Y is a direction from the anode 101 to the cathode 102.

By providing the hole transport unit 105 between the anode 101 and the light-emitting unit 104, the hole injection and transport efficiency of the light-emitting device 10 may be improved, and the luminous efficiency of the light-emitting device 10 may be improved.

In some embodiments, as shown in FIG. 4, the charge generation layer 6 includes a second hole blocking layer 82, a second electron transport layer 92, an electron generation layer 301, a hole generation layer 302, a second hole transport layer 32 and a second electron blocking layer 42 that are stacked in the first direction Y.

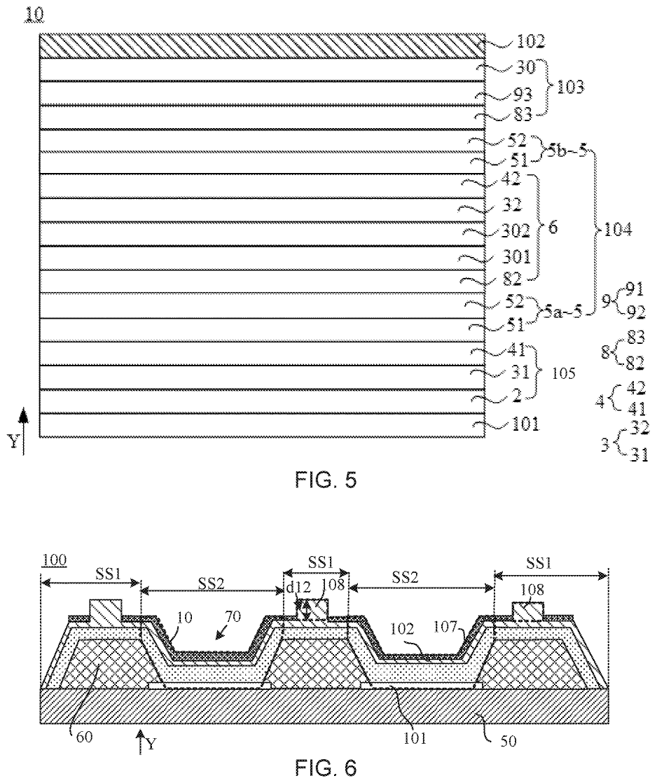

In some embodiments, as shown in FIG. 5, the charge generation layer 6 includes a second hole blocking layer 82, an electron generation layer 301, a hole generation layer 302, a second hole transport layer 32 and a second electron blocking layer 42 that are stacked in the first direction Y.

The charge generation layer 6 not only has a function of connecting two adjacent light-emitting layers 5, but also may improve injection and transport functions of charges, where the charges represent electrons or holes.

In some embodiments, as shown in FIGS. 4 and 5, the hole mobility of the first hole transport layer 31 is greater than the hole mobility of the first electron blocking layer 41. The hole mobility of the second hole transport layer 32 is greater than the hole mobility of the second electron blocking layer 42.

For example, as shown in FIG. 4, the first hole transport layer 31 and the first electron blocking layer 41 are disposed adjacently, and the hole mobility of the first hole transport layer 31 is greater than the hole mobility of the first electron blocking layer 41.

The second hole transport layer 32 and the second electron blocking layer 42 are disposed adjacently, and the hole mobility of the second hole transport layer 32 is greater than the hole mobility of the second electron blocking layer 42.

It may also be said that in a structure in which a hole transport layer 3 and an electron blocking layer 4 are disposed adjacently, the hole mobility of the hole transport layer 3 is greater than the hole mobility of the electron blocking layer 4. The hole transport layers 3 include a first hole transport layer 31 and a second hole transport layer 32, and the electron blocking layers 4 include a first electron blocking layer 41 and a second electron blocking layer 42.

The setting of the hole mobility of the hole transport layer 3 being greater than the hole mobility of the electron blocking layer 4 may increase an energy level barrier of the hole transport layer 3 and the electron blocking layer 4 that are disposed adjacently, and prevent an excessive amount of holes from being transmitted to the electron blocking layer 4 too quickly, so as to solve the problem of holes accumulating between the electron blocking layer 4 and the light-emitting layer 5 and improve the case of the recombination area being close to the electron blocking layer 4. Thus, it may effectively prevent holes from being accumulated at an interface between the light-emitting layer 5 and the electron blocking layer 4, and enable the holes to move towards the light-emitting layer 5 well, thereby improving the efficiency and life of the light-emitting device 10.

For example, the hole mobility of the hole transport layer 3 is in a range of 1×10⁻⁴ cm²/(V·s) to 1×10⁻⁶ cm²/(V·s), and the hole mobility of the hole transport layer 3 is, for example, 1×10⁻⁴ cm²/(V·s), 1×10⁻⁵ cm²/(V·s) or 1×10⁻⁶ cm²/(V·s), there is no limit here. The hole mobility of the electron blocking layer 4 is in a range of 1×10⁻⁵ cm²/(V·s) to 1×10⁻⁷ cm²/(V·s), and the hole mobility of the electron blocking layer 4 is, for example, 1×10⁻⁵ cm²/(V·s), 1×10⁻⁶ cm²/(V·s) or 1×10⁻⁷ cm²/(V·s), there is no limit here.

In some embodiments, as shown in FIGS. 4 and 5, triplet energy levels T5 of the electron blocking layers 4 are greater than the triplet energy levels of the host materials, where the electron blocking layers 4 include the first electron blocking layer 41 and the second electron blocking layer 42.

In some examples, as shown in FIG. 4, the first light-emitting layer 5a is disposed adjacent to the first electron blocking layer 41. The first light-emitting layer 5a includes a first light-emitting sub-layer 51 and a second light-emitting sub-layer 52, the first light-emitting sub-layer 51 includes a first host material and a first guest material, and the second light-emitting sub-layer 52 includes a second host material and a second guest material. The host material includes the first host material and the second host material, and the guest material includes the first guest material and the second guest material. A triplet energy level T51 of the first electron blocking layer 41 is greater than the triplet energy level T1 of the first host material, that is, T51>T1. Moreover, it can be known from the above about the triplet energy level T1 of the first host material and the triplet energy level T2 of the second host material that the triplet energy level T1 of the first host material is greater than the triplet energy level T2 of the second host material, that is, the triplet energy level T51 of the first electron blocking layer 41 is greater than the triplet energy levels of the host materials.

In some examples, as shown in FIG. 4, the second light-emitting layer 5b is disposed adjacent to the second electron blocking layer 42. The second light-emitting layer 5b includes a first light-emitting sub-layer 51 and a second light-emitting sub-layer 52. Similar to the first electron blocking layer 41, a triplet energy level T52 of the second electron blocking layer 42 is greater than the triplet energy levels of the host materials.

For example, the triplet energy level T5 of the electron blocking layer 4 is greater than or equal to 2.2 eV.

By setting the triplet energy level T5 of the electron blocking layer 4 to be greater than the triplet energy level of the host material, electrons and holes may generate excitons in an area where the light-emitting layer 5 is located, which is beneficial to the balance of the excitons, thereby improving the efficiency and life of the light-emitting device 10.

In some embodiments, as shown in FIGS. 1A to 5, the light-emitting device 10 further includes an electron transport unit 103 provided between the cathode 102 and the light-emitting unit 104. The electron transport unit 103 includes a first hole blocking layer 83, a first electron transport layer 93 and an electron injection layer 30 that are stacked in the first direction Y.

By providing the electron transport unit 103 between the cathode 102 and the light-emitting unit 104, the electron injection and transport efficiency of the light-emitting device 10 may be improved, and the luminous efficiency of the light-emitting device 10 may be improved.

In some embodiments, as shown in FIG. 4, a dimension d1 of the anode 101 in the first direction Y is in a range of 80 nm to 200 nm, inclusive.

It can be understood that the dimension d1 of the anode 101 in the first direction Y is the thickness of the anode 101. The same goes for the following, that is, a dimension of a film layer in the first direction Y in the following refers to the thickness of the film layer.

For example, the dimension d1 of the anode 101 in the first direction Y is 80 nm, 120 nm, 150 nm or 200 nm, and is not limited here.

For example, the anode 101 includes a material with a high work function. In a case of being applied to a light-emitting device 10 with a bottom emission structure, indium zinc oxide (IZO) or indium tin oxide (ITO) may be used as the anode 101. In a case of being applied to a light-emitting device 10 with a top emission structure, a composite structure of a transparent oxide layer, such as silver (Ag)/indium tin oxide (ITO) or silver (Ag)/indium zinc oxide (IZO), may be used as the anode 101. In a case where the composite structure of the transparent oxide layer is used as the anode 101, a thickness of a metal layer is in a range of 80 nm to 100 nm, inclusive, and a thickness of the metal oxide is in a range of 5 nm to 10 nm, inclusive. For example, the thickness of the metal layer Ag (silver) is 80 nm, 90 nm or 100 nm, which is not limited here; and the thickness of the metal oxide indium tin oxide (ITO) is 5 nm or 10 nm, which is not limited here. The average reflectivity of the visible area of the anode 101 is in a range of 85% to 95%, inclusive.

It will be noted that the light-emitting device 10 with the bottom emission structure refers to that the anode 101 is used as a transparent electrode and the cathode 102 is used as a reflective electrode; while the light-emitting device 10 with the top emission structure refers to that the anode 101 is used as a reflective electrode and the cathode 102 is used as a transparent electrode.

In some embodiments, as shown in FIG. 4, a dimension d2 of the hole injection layer 2 in the first direction Y may be in a range of 5 nm to 20 nm, inclusive.

For example, the dimension d2 of the hole injection layer 2 in the first direction Y is 5 nm, 10 nm, 15 nm or 20 nm, and is not limited here.

The main function of the hole injection layer 2 is to reduce the hole injection barrier and improve the hole injection efficiency. For example, the material of the hole injection layer 2 includes HATCN (a structure thereof refers to the structural formula shown as PD below) or CuPc (copper phthalocyanine). The material of the hole injection layer 2 may also be p-type doped, the p-type doping materials include, for example, NPB:F4TCNQ or TAPC:MnO₃, and the doping concentration is in a range of 0.5% to 10%, inclusive.

In some embodiments, as shown in FIG. 4, a dimension d3 of the hole transport layer 3 in the first direction Y is in a range of 10 nm to 100 nm, inclusive. The hole transport layers 3 include a first hole transport layer 31 and a second hole transport layer 32.

For example, the dimension d3 of the first hole transport layer 31 in the first direction Y is 10 nm, 50 nm, 70 nm or 100 nm, and is not limited here.

For example, the dimension d3 of the second hole transport layer 32 in the first direction Y is 10 nm, 40 nm, 80 nm or 100 nm, and is not limited here.

It will be noted that dimensions d3 of the first hole transport layer 31 and the second hole transport layer 32 in the first direction Y may be equal or unequal.

For example, the material of the hole transport layer 3 includes carbazole or arylamine materials with high hole mobility. The highest occupied molecular orbital (HOMO) energy level of the material of the hole transport layer 3 is in a range of −5.2 eV to −5.6 eV, inclusive. For example, the highest occupied molecular orbital (HOMO) energy level of the material of the hole transport layer 3 is −5.2 eV, −5.3 eV, −5.4 eV, −5.5 eV or −5.6 eV, and there is no limit here.

For example, the hole transport layer 3 is formed by evaporation.

In some embodiments, as shown in FIG. 4, a dimension d4 of the electron blocking layer 4 in the first direction Y is in a range of 20 nm to 70 nm, inclusive. The electron blocking layers 4 include a first electron blocking layer 41 and a second electron blocking layer 42.

For example, the dimension d4 of the first electron blocking layer 41 in the first direction Y is 20 nm, 40 nm, 50 nm or 70 nm, and is not limited here.

For example, the dimension d4 of the second electron blocking layer 42 in the first direction Y is 20 nm, 30 nm, 60 nm or 70 nm, and is not limited here.

It will be noted that dimensions d4 of the first electron blocking layer 41 and the second electron blocking layer 42 in the first direction Y may be equal or unequal.

The main function of the electron blocking layer 4 is to transport holes and block electrons and excitons generated in the light-emitting layer 5.

In some embodiments, as shown in FIG. 4, a dimension d5 of the light-emitting layer 5 in the first direction Y is in a range of 5 nm to 45 nm, inclusive.

For example, the dimension d5 of the light-emitting layer 5 in the first direction Y is 5 nm, 15 nm, 30 nm or 45 nm, and is not limited here.

For example, as shown in FIG. 4, the light-emitting layer 5 includes a first light-emitting sub-layer 51 and a second light-emitting sub-layer 52. The dimension d51 of the first light-emitting sub-layer 51 in the first direction Y may be the same as or different from the dimension d52 of the second light-emitting sub-layer 52 in the first direction Y.

For example, the dimension d51 of the first light-emitting sub-layer 51 in the first direction Y is 6 nm, and the dimension d52 of the second light-emitting sub-layer 52 in the first direction Y is 10 nm.

It can be understood that a sum of the dimension d51 of the first light-emitting sub-layer 51 in the first direction Y and the dimension d52 of the second light-emitting sub-layer 52 in the first direction Y is the dimension of the light-emitting layer 5 in the first direction Y, that is, d5=d51+d52.

The dimensions d5 of the first light-emitting layer 5a and the second light-emitting layer 5b in the first direction Y may be equal or not equal.

For example, the first light-emitting sub-layer 51 includes a first host material and a first guest material, and a doping ratio of the first guest material is in a range of 0.5% to 20%, inclusive. For example, the doping ratio of the first guest material is 0.5%, 5%, 8%, 15%, 17% or 20%, and there is no limit here.

The second light-emitting sub-layer 52 includes a second host material and a second guest material, and a doping ratio of the second guest material may refer to the doping ratio of the first guest material, which is not described again here.

In some embodiments, as shown in FIG. 4, a dimension d6 of the hole blocking layer 8 in the first direction Y is in a range of 2 nm to 20 nm, inclusive. The hole blocking layer 8 includes a second hole blocking layer 82 and a first hole blocking layer 83.

For example, the dimension d6 of the second hole blocking layer 82 in the first direction Y is 2 nm, 10 nm, 15 nm or 20 nm, and is not limited here.

For example, the dimension d6 of the first hole blocking layer 83 in the first direction Y is 2 nm, 8 nm, 16 nm or 20 nm, and is not limited here.

It will be noted that the dimensions d6 of the second hole blocking layer 82 and the first hole blocking layer 83 in the first direction Y may be equal or unequal.

The main function of the hole blocking layer 8 is to transfer electrons and block holes and excitons generated in the light-emitting layer 5.

In some embodiments, as shown in FIG. 4, a dimension d7 of the electron transport layer 9 in the first direction Y is in a range of 20 nm to 70 nm, inclusive. The electron transport layer 9 includes a second electron transport layer 92 and a first electron transport layer 93.

For example, the dimension d7 of the second electron transport layer 92 in the first direction Y is 20 nm, 50 nm, 60 nm or 70 nm, and is not limited here.

For example, the dimension d7 of the first electron transport layer 93 in the first direction Y is 20 nm, 30 nm, 40 nm or 70 nm, and is not limited here.

It will be noted that the dimensions d7 of the second electron transport layer 92 and the first electron transport layer 93 in the first direction Y may be equal or unequal.

In some embodiments, as shown in FIG. 4, a dimension d8 of the electron injection layer 30 in the first direction Y is in a range of 0.5 nm to 10 nm, inclusive; a dimension d9 of the electron generation layer 301 in the first direction Y is in a range of 5 nm to 20 nm, inclusive; and a dimension d10 of the hole generation layer 302 in the first direction Y is in a range of 5 nm to 20 nm, inclusive.

For example, the dimension d8 of the electron injection layer 30 in the first direction Y is 0.5 nm, 5 nm, 7 nm or 10 nm, and is not limited here.

For example, the dimension d9 of the electron generation layer 301 in the first direction Y is 5 nm, 15 nm, 18 nm or 20 nm, and is not limited here.

For example, the electron generation layer 301 uses an electron transport material. For example, the electron generation layer 301 uses an anthracene derivative with a phosphorus-oxygen double bond or an azine material, and is formed by co-evaporation with metal lithium (Li) or ytterbium (Yb).

For example, the dimension d10 of the hole generation layer 302 in the first direction Y is 5 nm, 10 nm, 15 nm or 20 nm, and is not limited here.

In some embodiments, as shown in FIG. 4, a dimension d11 of the cathode 102 in the first direction Y is in a range of 10 nm to 30 nm, inclusive.

For example, the dimension d11 of the cathode 102 in the first direction Y is 10 nm, 15 nm, 20 nm or 30 nm, and is not limited here.

For example, in a case of being applied to a light-emitting device 10 with a top emission structure, the cathode 102 is formed by using magnesium (Mg), silver (Ag) or aluminum (Al) through an evaporation process, or the cathode 102 is formed by using a magnesium silver (MgAg) alloy, and a mass ratio of the magnesium silver (MgAg) alloy is in a range of 3:7 to 1:9, inclusive. The cathode 102 formed by the above metal has a light transmittance in a range of 50% to 60% at a wavelength of 530 nm.

In some embodiments, as shown in FIG. 6, a resistance improvement layer 107 is further provided on a side of the cathode 102 away from the anode 101. The material of the resistance improvement layer 107 includes a fluorine-containing organic material.

For example, the material of the resistance improvement layer 107 is a material with low affinity and low adhesion, which is beneficial to the patterning of the cathode 102 and facilitates formation of an auxiliary cathode 108. For introduction of the auxiliary cathode 108, reference may be made to the following content, and details are not provided here.

For example, the structure of the fluorine-containing organic material may be selected from any of the following structural formulas.

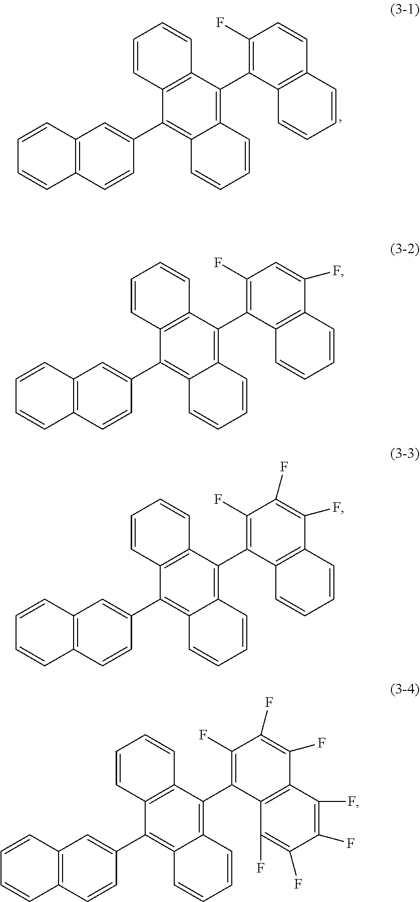 [SMILES: Fc1ccc2ccccc2c1-c1c2ccccc2c(-c2ccc3ccccc3c2)c2ccccc12 ; Fc1cc(F)c2ccccc2c1-c1c2ccccc2c(-c2ccc3ccccc3c2)c2ccccc12 ; Fc1c(F)c(-c2c3ccccc3c(-c3ccc4ccccc4c3)c3ccccc23)c2ccccc2c1F ; Fc1c(F)c(F)c2c(-c3c4ccccc4c(-c4ccc5ccccc5c4)c4ccccc34)c(F)c(F)c(F)c2c1F]

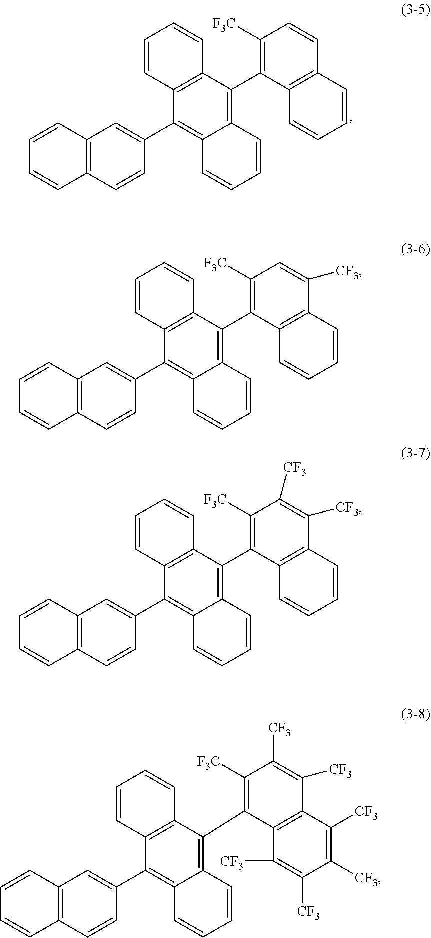 [SMILES: FC(F)(F)c1ccc2ccccc2c1-c1c2ccccc2c(-c2ccc3ccccc3c2)c2ccccc12 ; FC(F)(F)c1cc(C(F)(F)F)c2ccccc2c1-c1c2ccccc2c(-c2ccc3ccccc3c2)c2ccccc12 ; FC(F)(F)c1c(C(F)(F)F)c(C(F)(F)F)c2ccccc2c1-c1c2ccccc2c(-c2ccc3ccccc3c2)c2ccccc12 ; FC(F)(F)c1c(C(F)(F)F)c(C(F)(F)F)c2c(C(F)(F)F)c(C(F)(F)F)c(C(F)(F)F)c(C(F)(F)F)c2c1-c1c2ccccc2c(-c2ccc3ccccc3c2)c2ccccc12]

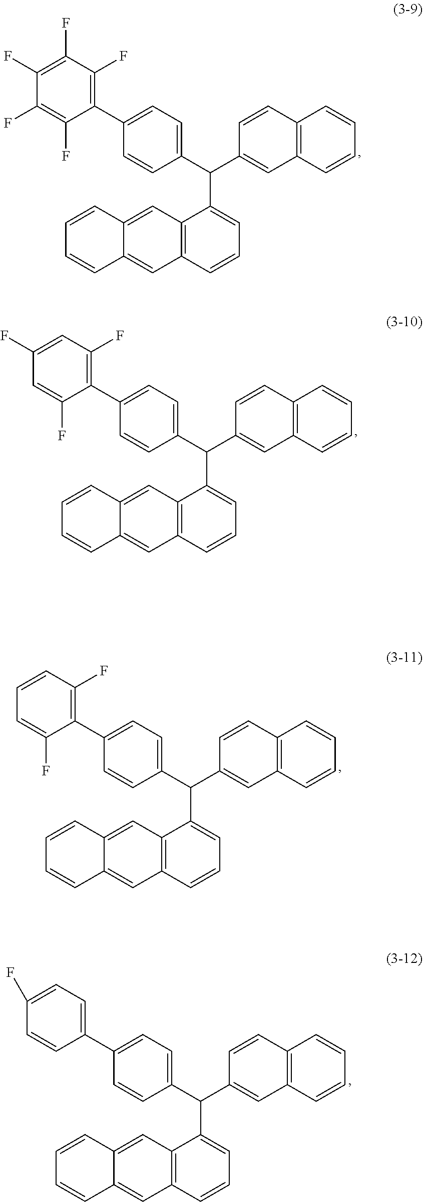 [SMILES: Fc1c(F)c(F)c(-c2ccc(C(c3ccc4ccccc4c3)c3cccc4cc5ccccc5cc34)cc2)c(F)c1F ; Fc1cc(F)c(-c2ccc(C(c3ccc4ccccc4c3)c3cccc4cc5ccccc5cc34)cc2)c(F)c1 ; Fc1cccc(F)c1-c1ccc(C(c2ccc3ccccc3c2)c2cccc3cc4ccccc4cc23)cc1 ; Fc1ccc(-c2ccc(C(c3ccc4ccccc4c3)c3cccc4cc5ccccc5cc34)cc2)cc1]

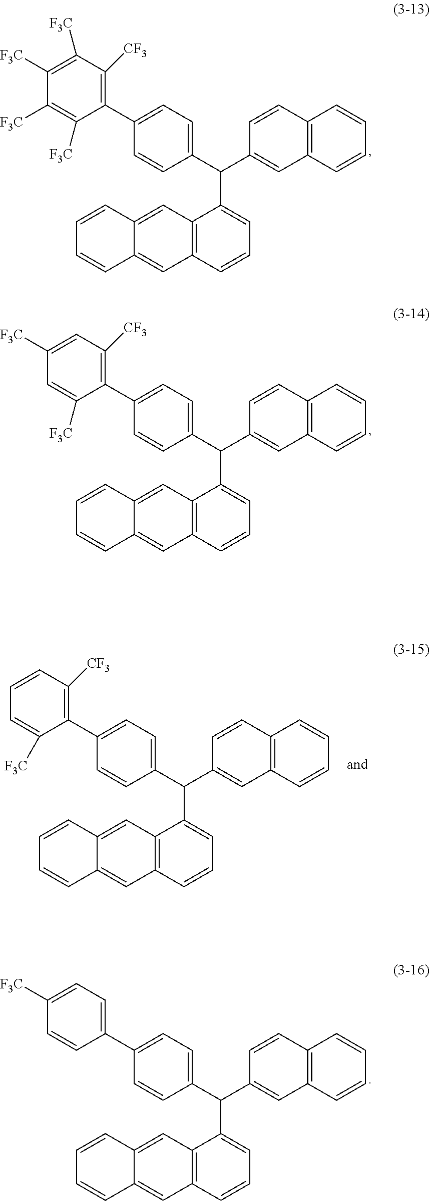 [SMILES: FC(F)(F)c1c(-c2ccc(C(c3ccc4ccccc4c3)c3cccc4cc5ccccc5cc34)cc2)c(C(F)(F)F)c(C(F)(F)F)c(C(F)(F)F)c1C(F)(F)F ; FC(F)(F)c1cc(C(F)(F)F)c(-c2ccc(C(c3ccc4ccccc4c3)c3cccc4cc5ccccc5cc34)cc2)c(C(F)(F)F)c1 ; FC(F)(F)c1cccc(C(F)(F)F)c1-c1ccc(C(c2ccc3ccccc3c2)c2cccc3cc4ccccc4cc23)cc1 ; FC(F)(F)c1ccc(-c2ccc(C(c3ccc4ccccc4c3)c3cccc4cc5ccccc5cc34)cc2)cc1]

For example, a fine metal mask (FMM) is used to form the resistance improvement layer 107 through an evaporation process.

The provision of the resistance improvement layer 107 may reduce a large voltage difference between the anode 101 and the cathode 102.

In order to objectively evaluate technical effects of the embodiments of the present disclosure, technical solutions provided by the present disclosure will be described in detail below through experimental examples and comparative examples.

Specifically, thicknesses materials of film layers of the light-emitting devices 10 provided in Comparative example (CE for short), Experimental example 1 (EE1 for short), Experimental example 2 (EE2 for short) and Experimental example 3 (EE3 for short) are shown in Table 1 below. The structures of the light-emitting devices 10 represented in Experimental example 1 and Experimental example 2 may refer to the structure shown in FIG. 1A (where the structure of the charge generation layer 6 may refer to the structure of the charge generation layer 6 in FIG. 5). The structure of the light-emitting device 10 represented in Experimental example 3 may refer to the structure shown in FIG. 5.

The hole injection layer 2 is represented by HIL, the first hole transport layer 31 is represented by HTL1, the first electron blocking layer 41 is represented by EBL1, the first light-emitting layer 5a is represented by EML1, the second hole blocking layer 82 is represented by is HBL2, the electron generation layer 301 is represented by N-CGL, the hole generation layer 302 is represented by P-CGL, the second hole transport layer 32 is represented by HTL2, the second electron blocking layer 42 is represented by EBL2, the second light-emitting layer 5b is represented by EML2, the first hole blocking layer 83 is represented by HBL3, the first electron transport layer 93 is represented by ETL3, and the electron injection layer 30 is represented by EIL.

It will be noted that, for example, the HIL in Experimental example 3 is 10 nm, which means that the thickness of the hole injection layer 2 in Experimental example 3 is 10 nm. The expressions of other film layers have similar meaning. Thicknesses of corresponding film layers in Experimental examples 1 to 3 are consistent. The thickness of the film layer in the Comparative example is designed based on the microcavity effect.

It will be noted that PD, HT-1, HT-2, BH, BH-1, BD, BD-1, HB-1, ET-1, LiQ, Yb and Mg:Ag in Table 1 represent materials used for formation of the film layers. Mg:Ag (2:8) means that a mass ratio of magnesium (Mg):silver (Ag) alloy in the material of the cathode 102 is 2:8, and BH:BD (3%) means that a mass ratio of the material represented by the structural formula of BD to EML (including EML1 and EML2) is 3%. The expressions of parameters have similar meaning. The structural formulas represented by PD, HT-1, HT-2, BH, BH-1, BD, BD-1, HB-1 and ET-1 are as follows.

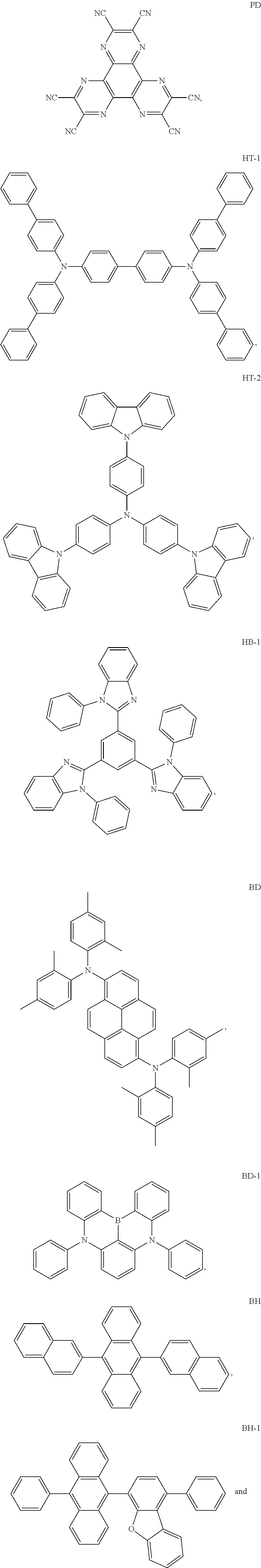

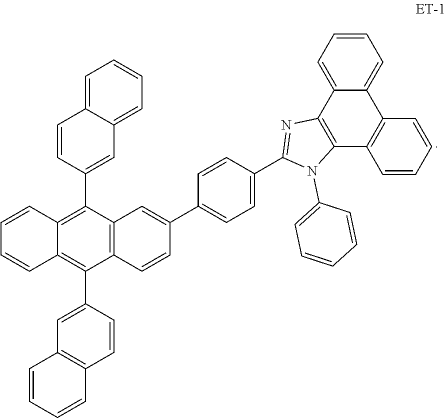 [SMILES: c1ccc(-n2c(-c3ccc(-c4ccc5c(-c6ccc7ccccc7c6)c6ccccc6c(-c6ccc7ccccc7c6)c5c4)cc3)nc3c4ccccc4c4ccccc4c32)cc1]

TABLE 1

| | HTL | | | | | | S-CGL | P-CGL |
|---|---|---|---|---|---|---|---|---|
| | HT-1:PD | HTL1 | EBL1 | EML1 | | HBL2 | ET-1:Li | HT-1:PD |
| | (3%) | HT-1 | HT-2 | BH:BD | | HB-1 | ( [symbol] %) | (5%) |
| CE | 20 [symbol] | 100 [symbol] | 5 [symbol] | 25 [symbol] | | 10 [symbol] | 0 | 0 |
| EE1 | 10 [symbol] | 20 [symbol] | 10 [symbol] | BH:BD(3%) | | 5 [symbol] | 20 [symbol] | 10 [symbol] |
| | | | | 16 [symbol] | | | | |
| EE2 | 10 [symbol] | 20 [symbol] | 10 [symbol] | BH:BD-1(3%) | | 5 [symbol] | 20 [symbol] | 10 [symbol] |
| | | | | 16 [symbol] | | | | |
| EE3 | 10 [symbol] | 20 [symbol] | 10 [symbol] | BH-1:BD-1 | BH:BD-1 | 5 [symbol] | 20 [symbol] | 10 [symbol] |
| | | | | [symbol] | 10 [symbol] | | | |

| | | | | | | ETL3 | | Cathod |
|---|---|---|---|---|---|---|---|---|
| | HTL2 | EBL2 | EML2 | | HBL3 | ET-1:LiQ | E [symbol] | Mg:Ag |
| | HT-1 | HT-2 | BH:BD | | HB-1 | (1:1) | [symbol] b | (2:8) |
| CE | 0 | 0 | 0 | | 0 | 0 | 5 [symbol] | 12 [symbol] |
| EE1 | 4 [symbol] | 10 [symbol] | BH:BD(3%) | | 5 [symbol] | 35 [symbol] | 2 [symbol] | 12 [symbol] |
| | | | 16 [symbol] | | | | | |
| EE2 | 4 [symbol] | 10 [symbol] | BH:BD-1(3%) | | 5 [symbol] | 35 [symbol] | 2 [symbol] | 12 [symbol] |
| | | | 16 [symbol] | | | | | |
| EE3 | 4 [symbol] | 10 [symbol] | BH-1:BD-1 | BH:BD-1 | 5 [symbol] | 15 [symbol] | 2 [symbol] | 12 [symbol] |
| | | | 6 [symbol] | 10 [symbol] | | | | |

[symbol]

indicates data missing or illegible when filed

The performance data of the light-emitting devices 10 represented by the above Comparative example and Experimental examples 1 to 3 are shown in Table 2.

TABLE 2

| | Current | | | | |
|---|---|---|---|---|---|
| | density | | | Color | |
| Device | (mA/cm²) | Voltage | Efficiency | coordinates | Life |
| Comparative | 15 | 100% | 100% | (0.140, 0.045) | 100% |
| Example | | | | | |
| EE 1 | | 180% | 180% | (0.140, 0.045) | 210% |
| EE 2 | | 180% | 205% | (0.138, 0.044) | 230% |
| EE 3 | | 172% | 221% | (0.140, 0.042) | 301% |

It can be seen from Table 2 that the device lives and efficiencies of the light-emitting devices 10 provided by the technical solutions of the present disclosure are greatly improved. The color coordinates are indicators of the light-emitting device 10 for characterizing color, and indicate that the light-emitting devices 10 provided by the technical solutions of the present disclosure have relatively high color saturation. In another aspect of the present disclosure, a display substrate 100 is provided.

As shown in FIG. 6, the display substrate 100 includes the light-emitting device 10 provided in any of the above embodiments. The light-emitting device 10 includes the anode 101 and the cathode 102 that are opposite.

As shown in FIG. 6, the display substrate 100 further includes a substrate 50, a pixel defining layer 60 provided on the substrate 50, and a plurality of pixel openings 70 defined by the pixel defining layer 60. Each pixel opening in the plurality of pixel openings 70 is provided with a light-emitting device 10 therein, and cathodes 102 of a plurality of light-emitting devices 10 are provided in a whole layer. That is, the cathodes 102 of the plurality of light-emitting devices 10 are a single film layer.

It will be noted that, as shown in FIG. 3B, the light-emitting device 10 includes a light-emitting layer 5 for emitting blue light, a red light-emitting layer 54 and a green light-emitting layer 53. The anode 101 includes a first anode, a second anode and a third anode in one to one correspondence to the light-emitting layer 5, the red light-emitting layer 54 and the green light-emitting layer 53.

A plurality of auxiliary electrodes 108 are provided on a side of the cathodes 102 away from the anodes 101. The orthographic projection of each auxiliary electrode 108 in the plurality of auxiliary electrodes 108 on the substrate 50 is located within the orthographic projection of the pixel defining layer 60 on the substrate 50.

That is, an area where the pixel definition layer 60 is located is a non-light-emitting area SS1, an area where the pixel opening 70 provided with the light-emitting device 10 therein is located is a light-emitting area SS2, and the auxiliary electrode 108 is located in the non-emitting area SS1. This may avoid affecting the light extraction efficiency.

By forming the auxiliary electrode 108 in the non-light-emitting area SS1, the problems of large surface resistance, uneven brightness, and a large voltage difference between the top and the bottom of the light-emitting device 10 may be improved without affecting the transmittance of the cathode 102 in the light-emitting area SS2.

For example, the substrate 50 may be an array substrate, and the array substrate includes a thin film transistor (TFT) array. For example, the array substrate includes a base, and an active layer, a gate insulation layer, a gate metal layer, an interlayer insulation layer, a source drain metal layer, and a planarization layer that are sequentially disposed on the base. The anode 101 is provided on a side of the planarization layer away from the base. In some other examples, the above substrate 50 may be a base substrate, and the display substrate 100 further includes other film layers (such as an active layer, a gate insulation layer, a gate metal layer, an interlayer insulation layer, a source drain metal layer, and a planarization layer) provided between the substrate 50 and the anode 101.

In some embodiments, as shown in FIG. 6, a dimension d12 of the auxiliary electrode 108 in the first direction Y is in a range of 10 nm to 20 nm, inclusive. The first direction Y is a direction from the anode 101 to the cathode 102.

For example, the dimension d12 of the auxiliary electrode 108 in the first direction Y is 10 nm, 15 nm, or 20 nm, and is not limited here.

The beneficial effects of the display substrate 100 provided by the present disclosure are the same as the beneficial effects of the light-emitting device 10 provided by the first aspect of the present disclosure, and details are not repeated here.

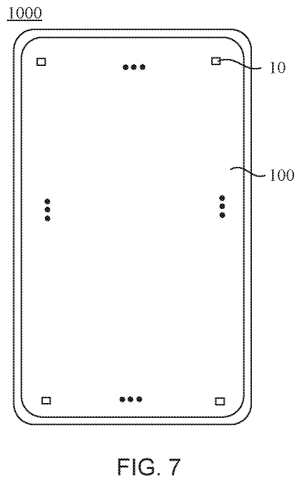

Some embodiments of the present disclosure provide a display apparatus 1000. As shown in FIG. 7, the display apparatus 1000 includes the display substrate 100 provided in the above embodiments.

The display apparatus 1000 provided by the embodiments of the present disclosure may be any apparatus that displays images whether in motion (such as a video) or fixed (such as a still image), and regardless of text or image. More specifically, it is expected that the embodiments may be implemented in or associated with a variety of electronic devices. The variety of electronic devices may include (but are not limited to), for example, mobile phones, wireless devices, personal digital assistants (PDAs), hand-held or portable computers, global positioning system (GPS) receivers/navigators, cameras, MPEG-4 Part 14 (MP4) video players, video cameras, game consoles, watches, clocks, calculators, TV monitors, flat-panel displays, computer monitors, car displays (e.g., odometer displays), navigators, cockpit controllers and/or displays, camera view displays (e.g., display of rear view camera in vehicles), electronic photos, electronic billboards or signs, projectors, architectural structures, packaging and aesthetic structures (e.g., displays for displaying an image of a piece of jewelry), etc.

The beneficial effects of the display apparatus 1000 are the same as the beneficial effects of the light-emitting device 10 provided by any of the above embodiments of the present disclosure, and details are not repeated here.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A light-emitting device, comprising: an anode and a cathode that are disposed oppositely, and a light-emitting unit disposed between the anode and the cathode, wherein
the light-emitting unit includes at least two light-emitting layers and a charge generation layer disposed between two adjacent light-emitting layers in the at least two light-emitting layers;
at least one light-emitting layer in the at least two light-emitting layers includes a first light-emitting sub-layer and a second light-emitting sub-layer, the first light-emitting sub-layer is closer to the anode than the second light-emitting sub-layer; and
the first light-emitting sub-layer includes a first host material and a first guest material, the second light-emitting sub-layer includes a second host material and a second guest material, and a triplet energy level of the first host material is greater than a triplet energy level of the second host material; triplet energy levels of host materials are greater than triplet energy levels of guest materials, wherein the host materials include the first host material and the second host material, and the guest materials include the first guest material and the second guest material.

2. The light-emitting device according to claim 1, wherein a difference between the triplet energy level of the first host material and the triplet energy level of the second host material is greater than 0.1 eV.

3. The light-emitting device according to claim 1, wherein a difference between a wavelength peak of light emitted by a light-emitting layer in the at least two light-emitting layers and a wavelength peak of light emitted by each of remaining light-emitting layers in the at least two light-emitting layers is less than or equal to 10 nm.

4. The light-emitting device according to claim 1, wherein each light-emitting layer in the at least two light-emitting layers are configured to emit blue light; a host material and a guest material of each light-emitting layer include fused ring compounds, and the fused ring compound contains three or more benzene rings.

5. The light-emitting device according to claim 4, wherein the fused ring compound includes any of substituted or unsubstituted anthracene, substituted or unsubstituted phenanthrene, substituted or unsubstituted pyrene, and substituted or unsubstituted fluorene.

6. The light-emitting device according to claim 4, wherein a fluorescence quantum yield of the light-emitting layer is greater than or equal to 85%, and the light-emitting layer is a film layer with horizontal orientation.

7. The light-emitting device according to claim 4, wherein the host material includes an anthracene derivative, and the guest material includes any of a pyrene derivative and a boron-containing derivative.

8. The light-emitting device according to claim 7, wherein the boron-containing derivatives is selected from any of structures represented by a following general formula (I): 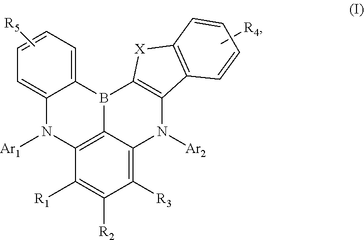
wherein X is selected from O, S and NR₆; R₁, R₂, R₃, R₄, R₅, R₆, Ar₁ and Ar₂ are same or different, and are each independently selected from any of H, D, F, substituted or unsubstituted alkyl, substituted or unsubstituted cycloalkyl, substituted or unsubstituted aryl group, substituted or unsubstituted heteroaromatic group, and a substituted or unsubstituted arylamino group.

9. The light-emitting device according to claim 4, wherein the host material includes an anthracene derivative containing deuterium; and the guest material includes a material with a thermal activation delay property.

10. The light-emitting device according to claim 1, wherein the light-emitting unit further includes a red light-emitting layer; the red light-emitting layer includes a phosphorescent material, and the red light-emitting layer contains two types of third host materials; and
the light-emitting unit further includes a green light-emitting layer; the green light-emitting layer includes a phosphorescent material, and the green light-emitting layer contains two types of fourth host materials.

11. The light-emitting device according to claim 1, further comprising a hole transport unit disposed between the anode and the light-emitting unit, wherein
the hole transport unit includes a hole injection layer, a first hole transport layer and a first electron blocking layer that are stacked in a first direction Y; the first direction is a direction from the anode to the cathode.

12. The light-emitting device according to claim 11, wherein the charge generation layer includes a second hole blocking layer, a second electron transport layer, an electron generation layer, a hole generation layer, a second hole transport layer and a second electron blocking layer that are stacked in the first direction; or
the charge generation layer includes a second hole blocking layer, an electron generation layer, a hole generation layer, a second hole transport layer and a second electron blocking layer that are stacked in the first direction.

13. The light-emitting device according to claim 12, wherein hole mobility of the first hole transport layer is greater than hole mobility of the first electron blocking layer; and/or
hole mobility of the second hole transport layer is greater than hole mobility of the second electron blocking layer.

14. The light-emitting device according to claim 13, wherein triplet energy levels of electron blocking layers are greater than the triplet energy levels of the host materials, and the electron blocking layers include the first electron blocking layer and the second electron blocking layer.

15. The light-emitting device according to claim 14, further comprising an electron transport unit disposed between the cathode and the light-emitting unit, wherein
the electron transport unit includes a first hole blocking layer, a first electron transport layer and an electron injection layer that are stacked in the first direction.

16. The light-emitting device according to claim 15, wherein
a dimension of the anode in the first direction is in a range of 80 nm to 200 nm, inclusive;
a dimension of the hole injection layer in the first direction is in a range of 5 nm to 20 nm, inclusive;
a dimension of each of hole transport layers in the first direction is in a range of 10 nm to 100 nm, inclusive;
a dimension of each of the electron blocking layers in the first direction is in a range of 20 nm to 70 nm, inclusive;
a dimension of each light-emitting layer in the first direction is in a range of 5 nm to 45 nm, inclusive;
a dimension of each of hole blocking layers in the first direction is in a range of 2 nm to 20 nm, inclusive;
a dimension of each of electron transport layers in the first direction is in a range of 20 nm to 70 nm, inclusive;
a dimension of the electron injection layer in the first direction is in a range of 0.5 nm to 10 nm, inclusive;
a dimension of the electron generation layer in the first direction is in a range of 5 nm to 20 nm, inclusive;
a dimension of the hole generation layer in the first direction is in a range of 5 nm to 20 nm, inclusive;
a dimension of the cathode in the first direction is in a range of 10 nm to 30 nm, inclusive;
wherein the hole transport layers include the first hole transport layer and the second hole transport layer; the hole blocking layers include the second hole blocking layer and the first hole blocking layer; and the electron transport layers include the second electron transport layer and the first electron transport layer.

17. The light-emitting device according to claim 1, further comprising a resistance improvement layer is disposed on a side of the cathode away from the anode; or
the light-emitting device further comprising a resistance improvement layer disposed on a side of the cathode away from the anode; wherein a material of the resistance improvement layer includes a fluorine-containing organic material.

18. (canceled)

19. A display substrate, comprising light-emitting devices each according to claim 1, the light-emitting device including an anode and a cathode that are disposed oppositely;
the display substrate further comprising: a substrate, a pixel defining layer disposed on the substrate, and a plurality of pixel openings defined by the pixel defining layer; each pixel opening in the plurality of pixel openings being provided with a light-emitting device therein; and cathodes of the light-emitting devices being disposed in a whole layer; and
the display substrate further comprising a plurality of auxiliary electrodes disposed on a side of the cathode away from the anode, and an orthographic projection of each auxiliary electrode in the plurality of auxiliary electrodes on the substrate being located within an orthographic projection of the pixel defining layer on the substrate.

20. The display substrate according to claim 19, wherein a dimension of the auxiliary electrode in a first direction is in a range of 10 nm to 20 nm, inclusive; the first direction is a direction from the anode to the cathode.

21. A display apparatus, comprising the display substrate according to claim 19.
